(19) United States
(12) Patent Application Publication
(10) Pub. No.: US 2015/0129132 A1
(43) Pub. Date: May 14, 2015

(54) SHOWERHEAD AND APPARATUS FOR PROCESSING A SUBSTRATE INCLUDING THE SAME

(71) Applicant: SAMSUNG ELECTRONICS CO., LTD., Suwon-si (KR)

(72) Inventors: Hong-Taek LIM, Anyang-si (KR); Ki-Kone KIM, Suwon-si (KR); Ho-Jun KIM, Gwacheon-si (KR); Jong-Yong BAE, Hwaseong-si (KR); Do-Hyung KIM, Uijeongbu-si (KR); Jai-Hyung WON, Seoul (KR); Seung-Moo LEE, Suwon-si (KR)

(21) Appl. No.: 14/339,650

(22) Filed: Jul. 24, 2014

(30) Foreign Application Priority Data
Nov. 13, 2013 (KR) 10-2013-0137293

(51) Int. Cl. C23C 16/455; C23C 16/46

(52) U.S. Cl. CPC C23C 16/45565; C23C 16/46
USPC 156/345.34; 118/725; 239/135

(57) ABSTRACT

A showerhead includes a body configured to receive a reaction gas, a nozzle on the body configured to inject the reaction gas to a substrate, and a plurality of conducting members in thermal contact with the body to conduct heat generated from the substrate.

### CROSS-REFERENCE TO RELATED APPLICATION

Korean Patent Application No. 10-2013-0137293, filed on Nov. 13, 2013, in the Korean Intellectual Property Office, and entitled: “Showerhead And Apparatus For Processing A Substrate Including The Same,” is incorporated by reference herein in its entirety.

### BACKGROUND

1. Field

Example embodiments relate to a showerhead and an apparatus for processing a substrate including the same. More particularly, example embodiments relate to a showerhead configured to inject a reaction gas to a substrate, and an apparatus for processing a substrate including the showerhead.

2. Description of the Related Art

Generally, an apparatus for processing a substrate may include a reaction chamber, a heater, and a showerhead. The substrate may be placed on an upper surface of the heater. The heater may heat the substrate. The showerhead may inject a reaction gas toward the substrate.

### SUMMARY

Example embodiments provide a showerhead having improved heat transfer characteristics.

Example embodiments also provide an apparatus for processing a substrate including a showerhead having improved heat transfer characteristics.

According to example embodiments, there is provided a showerhead including a body configured to receive a reaction gas, a nozzle on the body configured to inject the reaction gas to a substrate, and a plurality of conducting members in thermal contact with the body to conduct heat generated from the substrate.

In example embodiments, the conducting members may be concentratedly arranged at a portion of the body on which the heat may be concentrated.

In example embodiments, the conducting members may be arranged on an entire surface of the body. The conducting members may be spaced apart from each other by substantially the same interval.

In example embodiments, the conducting members may be arranged on a central portion of the body. The conducting members may be spaced apart from each other by substantially the same interval.

In example embodiments, the conducting members may include first conductors arranged on a central portion of the body, and second conductors arranged on an edge portion of the body.

In example embodiments, the first conductors and the second conductors may be spaced apart from each other by substantially the same interval.

In example embodiments, each of the conducting members may have an injecting hole configured to inject the reaction gas to the substrate.

In example embodiments, each of the conducting members may have a cylindrical shape.

According to other example embodiments, there is also provided an apparatus for processing a substrate, including a reaction chamber, a heater and a showerhead. The reaction chamber may be configured to receive the substrate. The heater may be positioned on a bottom surface of the reaction chamber to heat the substrate. The showerhead may include a body, a nozzle and a plurality of conducting members. The body may be arranged at an upper surface of the body to receive a reaction gas. The nozzle may be provided to the body to inject the reaction gas to the substrate. The conducting members may be provided to the body to conduct a heat generated from the substrate.

In example embodiments, the apparatus may further include an end plate arranged on a lower surface of the showerhead. The end plate may make contact with the conducting members.

In example embodiments, the apparatus may further include a base plate arranged on the upper surface of the showerhead. The base plate may make contact with the conducting members.

According to yet other example embodiments, there is also provided a showerhead including a body configured to receive a reaction gas, a nozzle on the body to inject the reaction gas to a substrate, and a plurality of conducting members on the body to conduct heat generated from the substrate, the plurality of conducting members defining upper and lower surfaces of the showerhead.

Upper and lower surfaces of the conducting members may be level with corresponding upper and lower surfaces of edges of the body.

The body may include a flat plate and a flange protruding along a perimeter of the flat plate to define the upper and lower surfaces of the edges of the body, the upper and lower surfaces of the conducting members extending from the flat plate to be level with upper and lower surfaces of the flange, respectively.

The conducting members may be arranged on an entire surface of the flat plate at equal distances from each other.

The conducting members may be arranged only on a predetermined portion of a surface of the flat plate at equal distances from each other, the predetermined portion corresponding to ab an area with increased generated heat.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 illustrates a perspective view of a showerhead in accordance with example embodiments;

FIG. 2 illustrates a cross-sectional view taken along line II-II′ in FIG. 1;

FIG. 3 illustrates a perspective view of a showerhead in accordance with example embodiments;

FIG. 4 illustrates a cross-sectional view taken along line IV-IV′ in FIG. 3;

FIG. 5 illustrates a perspective view of a showerhead in accordance with example embodiments;

FIG. 6 illustrates a cross-sectional view taken along line VI-VI′ in FIG. 5;

FIG. 7 illustrates a perspective view of a showerhead in accordance with example embodiments;

FIG. 8 illustrates a cross-sectional view taken along line VIII-VIII′ in FIG. 7;

FIG. 9 illustrates a perspective view of a showerhead in accordance with example embodiments;

FIG. 10 illustrates a cross-sectional view taken along line X-X′ in FIG. 9;

FIG. 11 illustrates a perspective view of a showerhead in accordance with example embodiments;

FIG. 12 illustrates a cross-sectional view taken along line XII-XII′ in FIG. 11;

FIG. 13 illustrates a perspective view of a showerhead in accordance with example embodiments;

FIG. 14 illustrates a cross-sectional view taken along line XIV-XIV′ in FIG. 13;

FIG. 15 illustrates a perspective view of a showerhead in accordance with example embodiments;

FIG. 16 illustrates a cross-sectional view taken along line XVI-XVI′ in FIG. 15; and

FIG. 17 illustrates a schematic cross-sectional view of an apparatus for processing a substrate including the showerhead in FIG. 1.

### DETAILED DESCRIPTION

Various example embodiments will be described more fully hereinafter with reference to the accompanying drawings, in which some example embodiments are shown. Example embodiments may, however, be embodied in many different forms and should not be construed as limited to those set forth herein. Rather, these example embodiments are provided so that this disclosure will be thorough and complete, and will fully convey the scope of exemplary implementations to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to illustrations that are schematic illustrations of idealized example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to limit the shape of a region of a device.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Showerhead

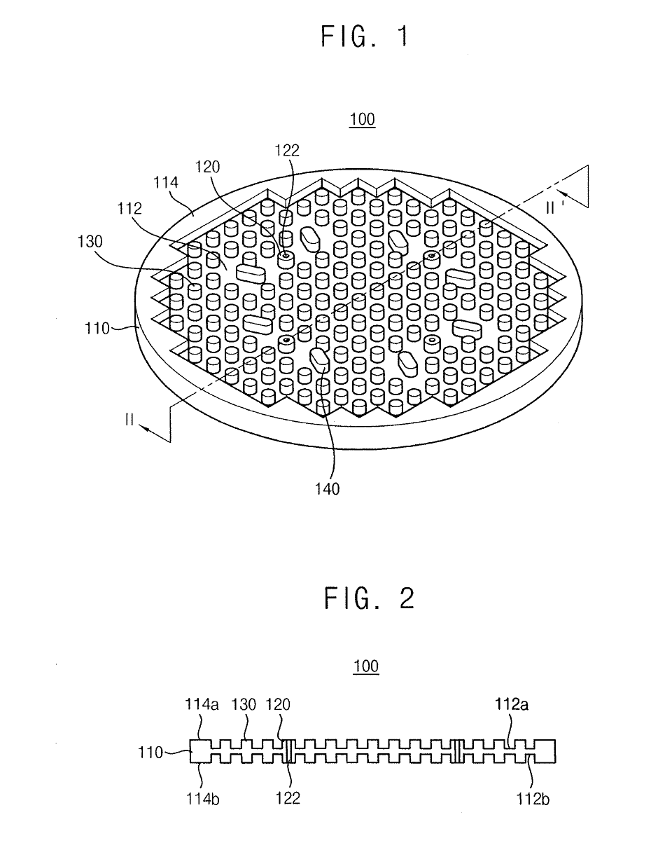

FIG. 1 illustrates a perspective view of a showerhead in accordance with example embodiments. FIG. 2 illustrates a cross-sectional view taken along line II-II′ in FIG. 1.

Referring to FIGS. 1 and 2, a showerhead 100 of this example embodiment may include a body 110, nozzles 120, a plurality of conducting members 130, and combining blocks 140.

In example embodiments, the body 110 may include a plate 112, e.g., a circular plate, and a flange 114 at an edge portion of the plate. The flange 114 may include an upper flange 114a protruding from the edge portion of the body 110 in an upward direction, and a lower flange 114b protruding from the edge portion of the body 110 in a downward direction. Thus, the body 110 may have an upper space defined by an upper surface 112a of the plate 112 and an inner surface of the upper flange 114a, and a lower space defined by a lower surface 112b of the plate 112 and an inner surface of the lower flange 114b. A reaction gas may be introduced into the upper space.

The nozzles 120 may be provided, e.g., directly, on the plate 112 of the body 110. For example, as illustrated in FIGS. 1-2, the nozzles 120 may be in the upper and lower spaces defined by the plate 112 and the flange 114. The nozzles 120 may inject the reaction gas from the upper space of the body 110 to a substrate. In example embodiments, the nozzles 120 may include four nozzles spaced apart from each other by a substantially same interval with respect to a center point of the body 110. Each of the nozzles 120 may have an injecting hole 122 configured to inject the reaction gas to the substrate. In example embodiments, the substrate may include, e.g., a semiconductor substrate, a glass substrate, etc.

The conducting members 130 may be provided, e.g., directly, on the body 110 so they are in thermal contact with the body 110. The conducting member 130 may conduct, e.g., dissipate, heat generated in the substrate, e.g., during processing thereof, to an outside. Because the conducting members 130 dissipate the heat from the substrate to the outside, e.g., via conduction, the heat transferred from the substrate to the showerhead 100 may be rapidly dissipated. As a result, the showerhead 100 may have improved heat transfer characteristics.

In example embodiments, as illustrated in FIGS. 1-2, the conducting members 130 may be uniformly arranged on the upper surface 112a and the lower surface 112b of the plate 112. The conducting members 130 may be spaced apart from each other by a substantially same interval. For example, each of the conducting members 130 may have a cylindrical shape. For example, as illustrated in FIG. 2, each conducting member 130 may extend to a same height as the flange 114, e.g., upper and lower surfaces of the conducting members 130 may be level with corresponding upper surface 114a and lower surface 114b of the flange 114 to define corresponding upper and lower surfaces of the showerhead 100. For example, the conducting members 130 may be integrally formed with the body 110, e.g., as a single and seamless structure. In another example, the conducting members 130 may be attached to or otherwise in thermal contact with the body 110. For example, the conducting members 130 may include a substantially same material as that of the body 110. In another example, the conducting members 130 may include a material different from that of the body 110.

The combining blocks 140 may be combined with, e.g., attached to, an end plate and a base plate of an apparatus for processing the substrate, as will be described in detail below with reference to FIG. 17. In example embodiments, two combining blocks 140 may be positioned at opposite sides of each of the nozzles 120.

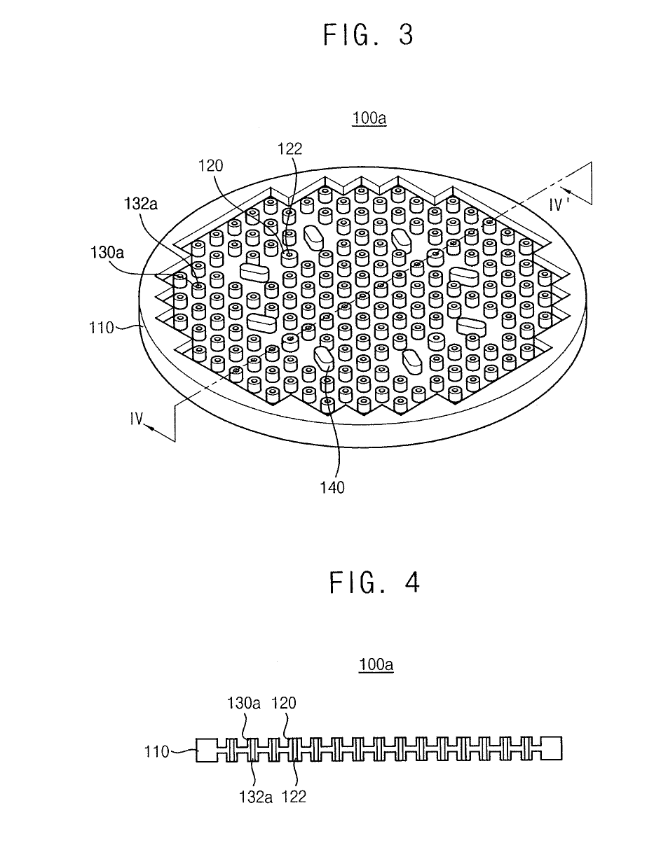

FIG. 3 illustrates a perspective view of a showerhead in accordance with example embodiments. FIG. 4 illustrates a cross-sectional view along line IV-IV′ in FIG. 3.

A showerhead 100a of this example embodiment may include substantially the same elements as those of the showerhead 100 in FIG. 1, except for the conducting members. Thus, same reference numerals refer to the same elements and any further illustrations with respect to the same elements may be omitted herein for brevity.

Referring to FIGS. 3 and 4, the showerhead 100a may include a plurality of conducting members 130a. The conducting members 130a may be substantially the same as the conducting members 130 in FIG. 1, except for further including injecting holes therethrough. That is, each of the conducting members 130a of this example embodiment may have an injecting hole 132a. Thus, the reaction gas may be injected through the injecting holes 132a of the conducting members 130a, as well as through the injecting holes 122 of the nozzles 120. As a result, the reaction gas may be more uniformly injected to the substrate.

According to this example embodiment, the conducting members 130a may have the gas inject function as well as the heat conduction function. Therefore, a layer on the substrate using the showerhead 100a may have improved quality.

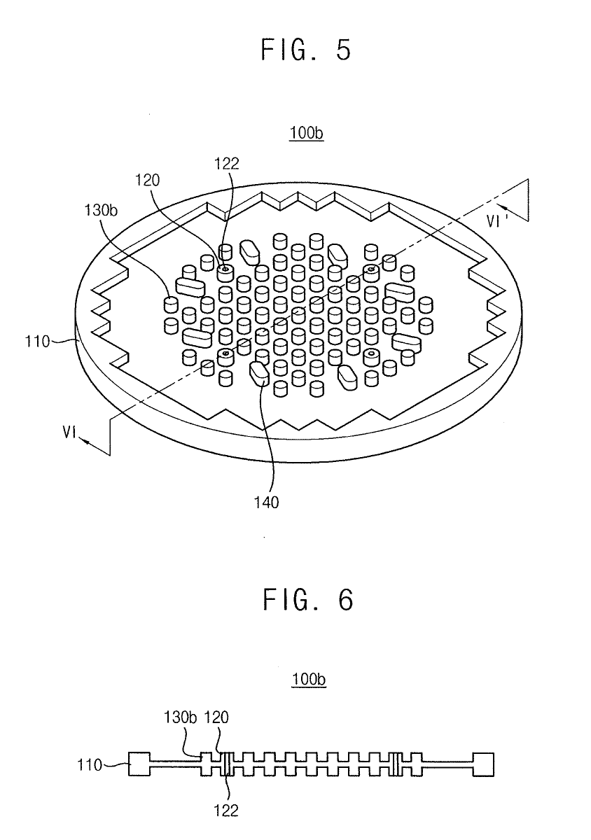

FIG. 5 illustrates a perspective view of a showerhead in accordance with example embodiments. FIG. 6 illustrates a cross-sectional view along line VI-VI′ in FIG. 5.

A showerhead 100b of this example embodiment may include substantially the same elements as those of the showerhead 100 in FIG. 1, except for the conducting members. Thus, the same reference numerals refer to the same elements and any further illustrations with respect to the same elements may be omitted herein for brevity.

Referring to FIGS. 5 and 6, the showerhead 100b may include a plurality of conducting members 130b. The conducting members 130b may be substantially the same as the conducting members 130 in FIG. 1, except for their position within the upper space of the body 110.

That is, the conducting members 130b of this example embodiment may be concentratedly arranged, e.g., only, at a central portion of the body 110. For example, the conducting members 130b may not be arranged at the edge portion of the body 110, e.g., an empty space larger than spacing between adjacent conductive members 130b may be defined on the upper surface 112a of the plate between the flange 114 and outermost conductive members 130b. Thus, the showerhead 100b may have a greater central heat dissipation efficiency than an edge heat dissipation efficiency. For example, the showerhead 100b may be used when heat is concentrated at the central portion of the body 110, e.g., when more heat is required to be removed from a region corresponding to the central portion of the body 110 than from edges thereof.

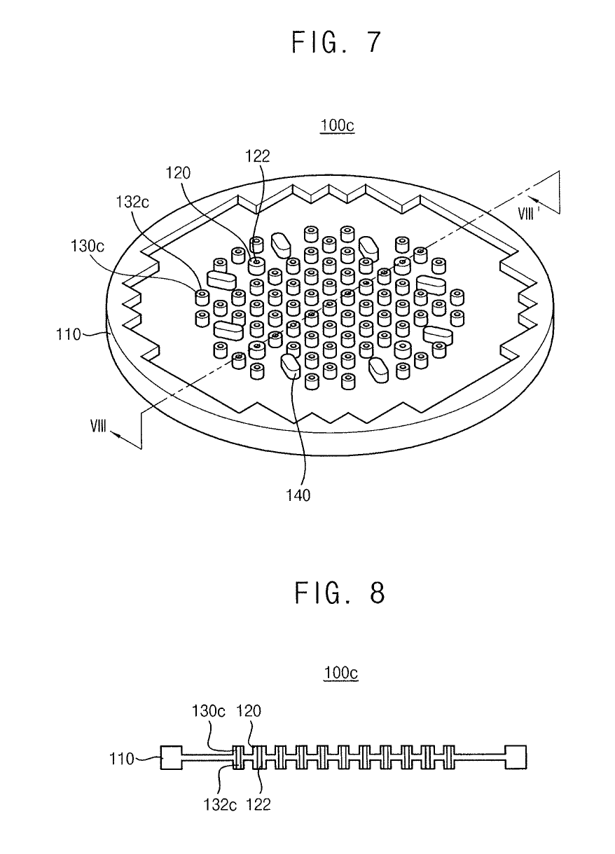

FIG. 7 illustrates a perspective view of a showerhead in accordance with example embodiments. FIG. 8 illustrates a cross-sectional view along line VIII-VIII′ in FIG. 7.

A showerhead 100c of this example embodiment may include substantially the same elements as those of the showerhead 100b in FIG. 5, except for the structure of the conducting members. Thus, the same reference numerals refer to the same elements and any further illustrations with respect to the same elements may be omitted herein for brevity.

Referring to FIGS. 7 and 8, the showerhead 100c may include a plurality of conducting members 130c. The conducting members 130c may be substantially the same as the conducting members 130b in FIG. 5, except for further including injecting holes therethrough. That is, each of the conducting members 130c of this example embodiment may have an injecting hole 132c. Thus, the reaction gas may be injected to the central portion of the substrate through the injecting holes 132c of the conducting members 130c as well as through the injecting holes 122 of the nozzles 120. As a result, the reaction gas may be more uniformly injected to the substrate.

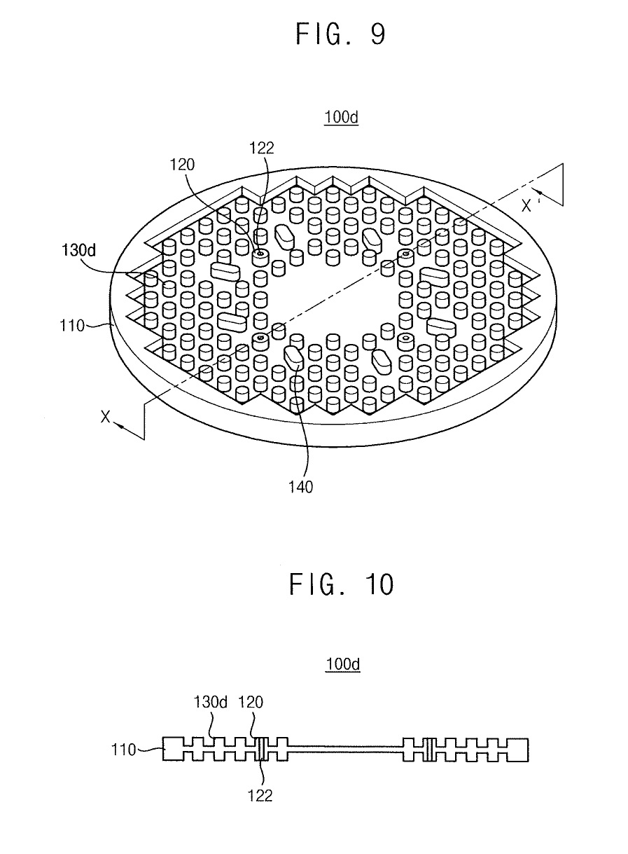

FIG. 9 illustrates a perspective view of a showerhead in accordance with example embodiments. FIG. 10 illustrates a cross-sectional view along line X-X′ in FIG. 9.

A showerhead 100d of this example embodiment may include substantially the same elements as those of the showerhead 100 in FIG. 1, except for the position of the conducting members. Thus, the same reference numerals refer to the same elements and any further illustrations with respect to the same elements may be omitted herein for brevity.

Referring to FIGS. 9 and 10, the showerhead 100d may include a plurality of conducting members 130d. The conducting members 130d may be substantially the same as the conducting members 130 in FIG. 1, except for their position within the upper space of the body 110.

That is, the conducting members 130d of this example embodiment may be concentratedly arranged, e.g., only, at the edge portion of the body 110. For example, the conducting members 130d may not be arranged at the central portion of the body 110. In other words, an empty space larger than spacing between adjacent conducting members 130d may be provided. Thus, the showerhead 100d may have a greater edge heat dissipation efficiency than a central heat dissipation efficiency. The showerhead 100d may be used when the heat is concentrated at the edge portion of the body 110.

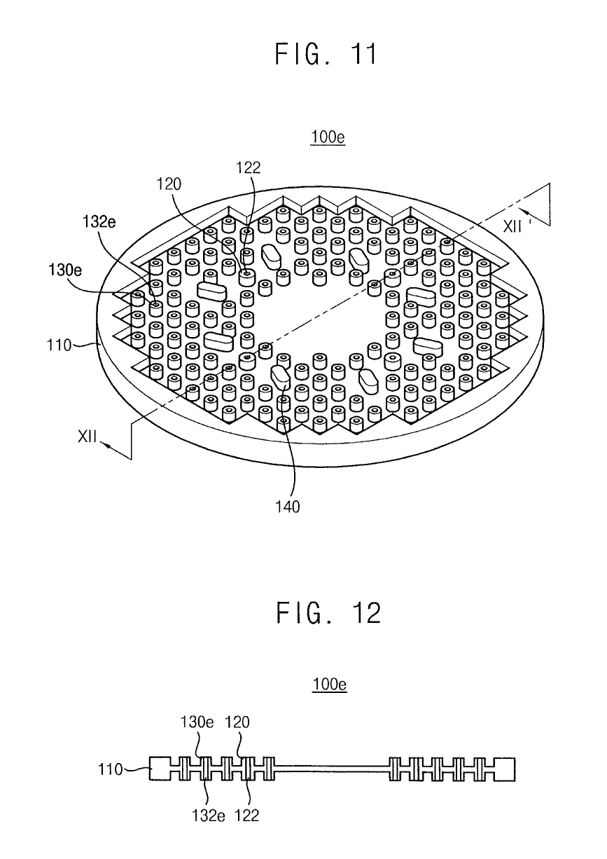

FIG. 11 illustrates a perspective view of a showerhead in accordance with example embodiments. FIG. 12 illustrates a cross-sectional view along line XII-XII′ in FIG. 11.

A showerhead 100e of this example embodiment may include substantially the same elements as those of the showerhead 100d in FIG. 9, except for the structure of the conducting members. Thus, the same reference numerals refer to the same elements and any further illustrations with respect to the same elements may be omitted herein for brevity.

Referring to FIGS. 11 and 12, the showerhead 100e may include a plurality of conducting members 130e. The conducting members 130e may be substantially the same as the conducting members 130d in FIG. 9, except for further including injecting holes therethrough. That is, each of the conducting members 130e of this example embodiment may have an injecting hole 132e. In other words, an empty space larger than spacing between adjacent conductive members 130e may be provided. Thus, the reaction gas may be injected to the edge portion of the substrate through the injecting holes 132e of the conducting members 130e as well as through the injecting holes 122 of the nozzles 120. As a result, the reaction gas may be more uniformly injected to the substrate.

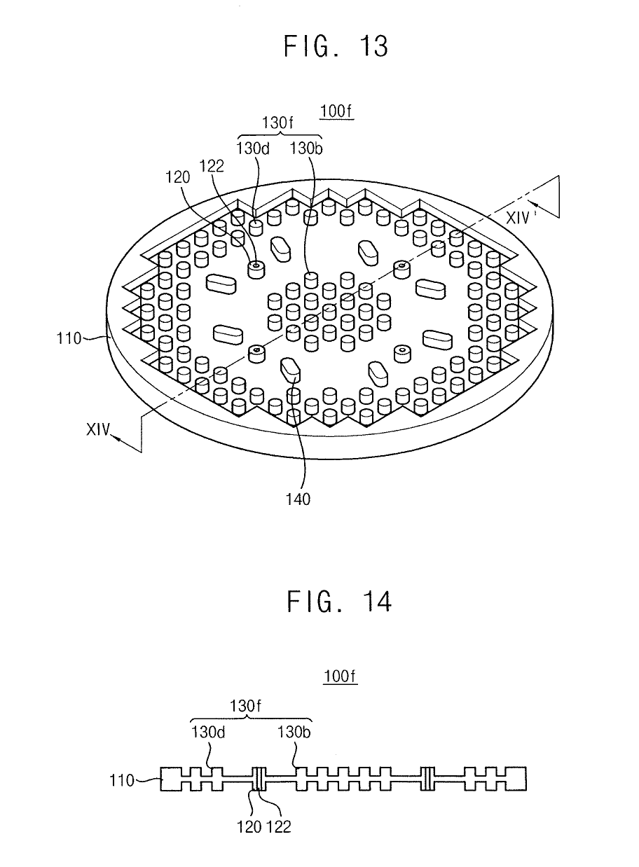

FIG. 13 illustrates a perspective view of a showerhead in accordance with example embodiments. FIG. 14 illustrates a cross-sectional view along line XIV-XIV′ in FIG. 13.

A showerhead 100f of this example embodiment may include substantially the same elements as those of the showerhead 100 in FIG. 1, except for the position of the conducting members. Thus, the same reference numerals refer to the same elements and any further illustrations with respect to the same elements may be omitted herein for brevity.

Referring to FIGS. 13 and 14, the showerhead 100f may include a plurality of conducting members 130f. The conducting members 130f may be substantially the same as the conducting members 130 in FIG. 1, except for their position on the body 110. That is, the conducting members 130f of this example embodiment may include first conductors and second conductors in different regions on the body 110.

In detail, the first conductors may be concentratedly arranged at the central portion of the body 110, e.g., as the conducting members 130b. The second conductors may be concentratedly arranged at the edge portion of the body 110, e.g., as the conducting members 130d. For example, the conducting members 130f may not be arranged at a middle portion of the body 110, e.g., at a portion of the body 110 that includes the nozzles 120. Thus, the showerhead 100f may have edge heat dissipation efficiency and central heat dissipation efficiency greater than middle heat dissipation efficiency. The showerhead 100f may be used when the heat is concentrated at the central portion and the edge portion of the body 110.

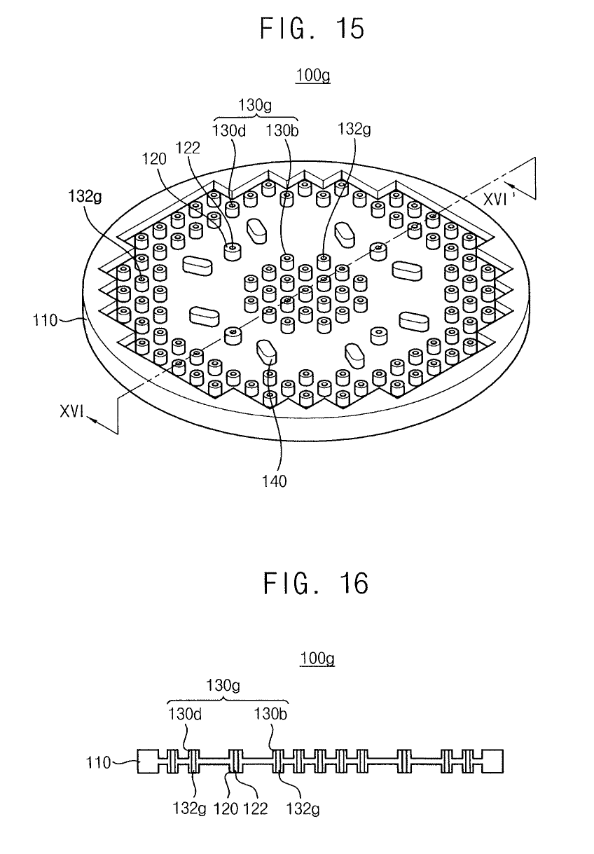

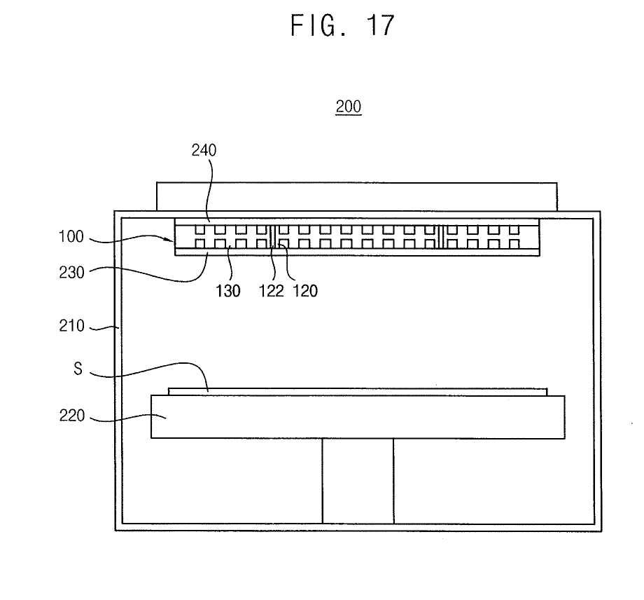

FIG. 15 illustrates a perspective view of a showerhead in accordance with example embodiments. FIG. 16 illustrates a cross-sectional view along line XVI-XVI′ in FIG. 15.

A showerhead 100g of this example embodiment may include substantially the same elements as those of the showerhead 100f in FIG. 13, except for the structure of the conducting members. Thus, the same reference numerals refer to the same elements and any further illustrations with respect to the same elements may be omitted herein for brevity.

Referring to FIGS. 15 and 16, the showerhead 100g may include a plurality of conducting members 130g. The conducting members 130g may be substantially the same as the conducting members 130f in FIG. 13, except for further including injecting holes therethrough. That is, each of the conducting members 130g of this example embodiment may have an injecting hole 132g. Thus, the reaction gas may be injected to the central portion and the edge portion of the substrate through the injecting holes 132g of the conducting members 130g as well as through the injecting holes 122 of the nozzles 120. As a result, the reaction gas may be more uniformly injected to the substrate.

In example embodiments, the conducting members may be concentratedly arranged at the central portion, the edge portion, etc., of the body 110. However, example embodiments are not limited thereto, e.g., the conducting members may be concentratedly arranged on any portion of the body 110 on which heat may be concentrated to rapidly dissipate the heat from the portion of the body 110.

Apparatus for Processing a Substrate

FIG. 17 illustrates a cross-sectional view of an apparatus for processing a substrate. The apparatus in FIG. 17 includes the showerhead in FIG. 1.

Referring to FIG. 17, an apparatus 200 for processing a substrate in accordance with this example embodiment may include a reaction chamber 210, a heater 220, the showerhead 100, an end plate 230, and a base plate 240.

The reaction chamber 210 may have an inner space where a substrate S may be received. The reaction chamber 210 may have an inlet through which the reaction gas may be introduced into the reaction chamber 210, and an outlet through which byproducts may be exhausted from the reaction chamber 210.

The heater 220 may be positioned adjacent a bottom surface of the reaction chamber 210 to heat the substrate S. The substrate S may be placed adjacent, e.g., in thermal contact with, an upper surface of the heater 220. In example embodiments, the heater 220 may include a coil heater built in a stage configured to support the substrate S.

The showerhead 100 may be provided adjacent to an upper surface of the reaction chamber 210, i.e., spaced apart form the heater 220. The showerhead 100 may be in fluid communication with the inlet and the outlet. In example embodiments, the showerhead 100 in FIG. 17 is the same as the showerhead 100 in FIG. 1. However, example embodiments are not limited thereto, e.g., the apparatus 200 may include any one of the showerhead 100a in FIG. 3, the showerhead 100b in FIG. 5, the showerhead 100c in FIG. 7, the showerhead 100d in FIG. 9, the showerhead 100e in FIG. 11, the showerhead 100f in FIG. 13, or the showerhead 100g in FIG. 15.

The end plate 230 may be adjacent the lower surface of the showerhead 100 to define the lower space of the showerhead 100. The end plate 230 may be fixed to the combining blocks 140 of the showerhead 100. The end plate 230 may make thermal contact, e.g., direct contact, with the conducting members 130 of the showerhead 100.

The base plate 240 may be adjacent the upper surface of the showerhead 100 to define the upper surface of the showerhead 100. The base plate 240 may be fixed to the combining blocks 140 of the showerhead 100. The base plate 240 may be secured to the reaction chamber 210. The base plate 240 may make thermal contact, e.g., direct contact, with the conducting members 130 of the showerhead 100. In other words, the conducting members 130 may extend from the end plate 230 to the base plate 240, and are in thermal contact, e.g., direct contact, with each of the end plate 230 and the base plate 240, so heat may be conducted through the showerhead 100 via the conductive members 130.

In detail, in example embodiments, the heat generated from the heater 220 and the substrate S may be dissipated to the outside of the reaction chamber 210 through the end plate 230, the showerhead 100, and the base plate 240. Because the showerhead 100 includes the conducting members 130, the heat in the showerhead 100 may be effectively transferred from the end plate 230 to the base plate 240 through the conducting members 130. Therefore, the heat transfer characteristic from the end plate 230 through the showerhead 100 may be remarkably improved. As a result, a deposition rate of a layer on the substrate S may be improved so that the layer may have improved quality. In example embodiments, the apparatus 200 may include a deposition apparatus, an etching apparatus, etc.

By way of summary and review, the heat transfer characteristic from a heater to a showerhead may have a great influence on the quality of a layer formed on a substrate. For example, when heat is not effectively dissipated from the showerhead or is concentrated on a specific region of the showerhead, abnormal deposition rate of the layer on the substrate may be generated.

Therefore, according to example embodiments, conducting members are formed in the showerhead in order to rapidly conduct, e.g., dissipate, the heat transferred to the showerhead from the heater and substrate, so that the showerhead may have improved heat transfer characteristic. Particularly, the conducting members may be concentratedly arranged at a specific portion of the showerhead, e.g., where heat is concentrated in accordance with kinds of layers to be formed, so that a processing, e.g., deposition, rate of the layer on the substrate may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A showerhead, comprising:
a body configured to receive a reaction gas;
a nozzle on the body configured to inject the reaction gas to a substrate; and
a plurality of conducting members in thermal contact with the body to conduct heat generated from the substrate.

2. The showerhead as claimed in claim 1, wherein a concentration of conducting members on a portion of the body on which the heat is concentrated is higher than on other portions of the body.

3. The showerhead as claimed in claim 1, wherein the conducting members are arranged on an entire surface of the body.

4. The showerhead as claimed in claim 3, wherein the conducting members are spaced apart from each other by a substantially same interval.

5. The showerhead as claimed in claim 1, wherein a concentration of conducting members on a central portion of the body is higher than on other portions of the body.

6. The showerhead as claimed in claim 5, wherein the conducting members are spaced apart from each other by a substantially same interval.

7. The showerhead as claimed in claim 1, wherein a concentration of conducting members on an edge portion of the body is higher than on other portions of the body.

8. The showerhead as claimed in claim 7, wherein the conducting members are spaced apart from each other by a substantially same interval.

9. The showerhead as claimed in claim 1, wherein the conducting members include:
first conductors arranged on a central portion of the body; and
second conductors arranged on an edge portion of the body.

10. The showerhead as claimed in claim 9, wherein, within the central portion, the first conductors are spaced apart from each other by a substantially same interval, and, within the edge portion, the second conductors are spaced apart from each other by the substantially same interval.

11. The showerhead as claimed in claim 1, wherein each of the conducting members has an injecting hole to inject the reaction gas to the substrate.

12. The showerhead as claimed in claim 1, wherein each of the conducting members has a cylindrical shape.

13. An apparatus for processing a substrate, the apparatus comprising:
a reaction chamber configured to receive the substrate;
a heater positioned on a bottom surface of the reaction chamber to heat the substrate; and
a showerhead including:
a body configured to receive a reaction gas,
a nozzle on the body configured to inject the reaction gas to the substrate, and
a plurality of conducting members in thermal contact with the body to conduct heat generated from the substrate.

14. The apparatus as claimed in claim 13, further comprising an end plate on a lower surface of the showerhead and thermally contacting the conducting members.

15. The apparatus as claimed in claim 14, further comprising a base plate on an upper surface of the showerhead and thermally contacting the conducting members.

16. A showerhead, comprising:
a body configured to receive a reaction gas;
a nozzle on the body configured to inject the reaction gas to a substrate; and
a plurality of conducting members in thermal contact with the body to conduct heat generated from the substrate, the plurality of conducting members defining upper and lower surfaces of the showerhead.

17. The showerhead as claimed in claim 16, wherein upper and lower surfaces of the conducting members are level with corresponding upper and lower surfaces of edges of the body.

18. The showerhead as claimed in claim 17, wherein the body includes a flat plate and a flange protruding along a perimeter of the flat plate to define the upper and lower surfaces of the edges of the body, the upper and lower surfaces of the conducting members extending from the flat plate to be level with upper and lower surfaces of the flange, respectively.

19. The showerhead as claimed in claim 18, wherein the conducting members are on an entire surface of the flat plate at equal distances from each other.

20. The showerhead as claimed in claim 18, wherein the conducting members are only on a predetermined portion of a surface of the flat plate at equal distances from each other, the predetermined portion corresponding to an area with increased generated heat.
